(19) United States
(12) Patent Application Publication
(10) Pub. No.: US 2022/0182586 A1
(43) Pub. Date: Jun. 9, 2022

(54) LASER PROJECTION DISPLAY APPARATUS AND METHOD FOR DRIVING LASER LIGHT SOURCE

(71) Applicant: Hitachi-LG Data Storage, Inc., Tokyo (JP)

(72) Inventors: Yuya OGI, Tokyo (JP); Shinsuke ONOE, Tokyo (JP); Tomoyuki NONAKA, Tokyo (JP)

(21) Appl. No.: 17/603,354

(22) PCT Filed: May 25, 2020
(86) PCT No.: PCT/JP2020/020438

§ 371 Date: Oct. 13, 2021

(30) Foreign Application Priority Data
Jul. 12, 2019 (JP) 2019-130388

(51) Int. Cl. H04N 9/31

(52) U.S. Cl. CPC H04N 9/3152; H04N 9/3194; H04N 9/3164; H04N 9/3161

(57) ABSTRACT

A laser projection display apparatus includes: a laser light source that generates laser lights of a plurality of colors; a laser light source driving unit that drives the laser light source; a light intensity detector that detects an intensity of the laser light; an overshoot current determining unit that determines a reference overshoot current for improving a rising response of the laser light source; and an overshoot current applying unit that applies an overshoot current to an image signal based on the reference overshoot current. The overshoot current determining unit supplies the overshoot current to the laser light source driving unit while changing the overshoot current, so as to cause the laser light source to emit light, and determines the reference overshoot current such that a light intensity detected when the laser light source emits light becomes a target value.

### TECHNICAL FIELD

The present invention relates to a laser projection display apparatus that displays images by scanning light emitted from a laser light source with a two-dimensional scanning mirror, and a method for driving a laser light source.

### BACKGROUND ART

In recent years, a laser projection display apparatus using a laser light source such as a semiconductor laser and a two-dimensional scanning mirror such as a micro electro mechanical systems (MEMS) mirror has been put into practical use. At this time, in order to make the emission light intensity of the laser light source constant, the following proposals have been made to correct a laser driving current immediately after the light emission starts.

For example, PTL 1 discloses a configuration in which waveform blunting of a laser light output is reduced by adding an auxiliary current called an assist current when a current pulse rises. This assist current is generated by at least two time constant circuits, and is attenuated in accordance with the time since the light emission starts. Furthermore, PTL 1 states a configuration in which a coefficient is introduced in consideration of a thermal factor remaining in the laser light source when the laser light is emitted, thereby reducing the waveform blunting of the light output even the pulsed light emission is continuously output.

### CITATION LIST

### Patent Literature

PTL 1: JP-A-2011-216662

### SUMMARY OF INVENTION

### Technical Problem

In a laser projection display apparatus, a laser driver is used as a current source for driving a laser light source such as the semiconductor laser. A switch element is incorporated in the laser driver, and a current flowing through the semiconductor laser is controlled by this switch element. However, a parasitic capacitance is present in a substrate or the like on which the switch element, the laser driver, and the laser light source are mounted. Therefore, when a current is to be flown in a stepwise manner from a state where no current flows at all, a certain time constant until the current becomes constant is generated. A current component that does not contribute to light emission is also present due to parasitic capacitance, heat conversion, or the like in the laser light source. These reasons lead to a first problem that the rising waveform of the laser light intensity is blunted, that is, the light intensity does not become constant instantaneously.

As a result, when a color image is displayed using semiconductor lasers of a plurality of colors, if the rising characteristics are different between the semiconductor lasers, a white content is visually recognized by a user as color unevenness when being displayed. In particular, in a case where the semiconductor laser is operated in the vicinity of a threshold current where the light output characteristic changes steeply with respect to a forward current of the semiconductor laser, the occurrence of color unevenness becomes significant.

Furthermore, the semiconductor laser has a second problem that in the characteristics of the laser light intensity (light output characteristics) with respect to the forward current fluctuate due to ambient temperature changes, and the laser light intensity decreases due to deterioration with time. In particular, a behavior of a rising response of the laser light intensity changes due to change in a slope efficiency which is a slope of the light intensity with respect to the forward current.

Here, the above first problem and second problem both relate to the light output characteristics of the semiconductor laser, and thus are mutually affected even if individually handled, and are difficult to be both satisfied at the same time.

For example, in the technique in PTL 1, the waveform blunting of the light intensity is reduced by applying an assist current (hereinafter, referred to as an “overshoot current”) when a current pulse rises. However, such technique is feedforward control in which the overshoot current is determined using a preset expression, and thus it is difficult to cope with the decrease in the intensity of the laser light due to the deterioration with time. Further, according to PTL 1, a peak value of the overshoot current can be changed with respect to the ambient temperature change. However, a ratio (attenuation rate) at which the overshoot current is attenuated in accordance with the time from the start of the light emission is constant, and thus it is not possible to cope with a change in the slope efficiency of the laser light output characteristics. For these reasons, the second problem that the behavior of the rising response of the laser light intensity changes due to the ambient temperature change or the deterioration with time is not solved.

The invention has been made in view of the above problems, and an object of the present invention is to prevent a change in rising response of a laser light intensity due to ambient temperature change or deterioration with time in a laser projection display apparatus.

### Solution to Problem

The invention relates to a laser projection display apparatus configured to display an image by projecting laser lights of a plurality of colors in accordance with an image signal. The laser projection display apparatus includes: a laser light source configured to generate the laser lights of a plurality of colors; a laser light source driving unit configured to drive the laser light source in accordance with the image signal; a light intensity detector configured to detect an intensity of the laser lights emitted from the laser light source; an overshoot current determining unit configured to determine a reference overshoot current for improving a rising response of the laser light source; and an overshoot current applying unit configured to apply an overshoot current to the image signal based on the reference overshoot current determined by the overshoot current determining unit. The overshoot current determining unit supplies the overshoot current to the laser light source driving unit while changing the overshoot current, so as to cause the laser light source to emit light, and determines the reference overshoot current such that the light intensity detected by the light intensity detector when the laser light source emits light becomes a target value.

In addition, the invention relates to a method for driving a laser light source when displaying an image by projecting laser lights of a plurality of colors in accordance with an image signal. The method for driving a laser light source includes: determining a reference overshoot current for improving a rising response of the laser light source in advance; and driving the laser light source by applying an overshoot current on the image signal based on the determined reference overshoot current. Determining the reference overshoot current includes: supplying the overshoot current while changing the overshoot current, so as to cause the laser light source to emit light; and determining the reference overshoot current such that the light intensity detected when the laser light source emits light becomes a target value.

### Advantageous Effect

According to the invention, it is possible to provide a laser projection display apparatus that displays a high-quality image that is unlikely to cause a user to visually recognize color unevenness by optimizing an applied waveform of an overshoot current with high accuracy by feedback, even an ambient temperature change or deterioration with time is present.

### BRIEF DESCRIPTION OF DRAWINGS

FIG. 1 is a block diagram showing an overall configuration of a laser projection display apparatus according to a first embodiment.

FIG. 2 is a diagram showing an internal configuration of an image processing unit and a laser light source driving unit.

FIG. 3 is a diagram schematically explaining an effect of applying an overshoot current.

FIG. 4A is a diagram showing a case where a monitor light emission is performed during a vertical blanking period.

FIG. 4B is a diagram showing an example of the monitor light emission in a light guide plate type display apparatus.

FIG. 5 is a diagram showing overshoot current determination by feedback.

FIG. 6 is a flowchart of the overshoot current determination.

FIG. 7 is a flowchart of an overshoot current determination of a second embodiment.

FIG. 8 is a diagram showing internal configurations of an image processing unit and a laser light source driving unit according to a third embodiment.

FIG. 9A is a diagram explaining correction of an overshoot current in accordance with a non-light emission period.

FIG. 9B is a diagram showing an example of a first LUT.

FIG. 9C is a flowchart of first LUT creation.

FIG. 10A is a diagram explaining correction of an overshoot current in accordance with a light emission period.

FIG. 10B is a diagram showing an example of a second LUT.

FIG. 10C is a flowchart of second LUT creation.

FIG. 11 a schematic diagram when the light emission period and the non-light emission period are repeated.

### DESCRIPTION OF EMBODIMENTS

Hereinafter, embodiments of the invention will be explained in detail with reference to drawings. The following explanation is for explaining an embodiment of the invention, and does not limit the scope of the invention. Therefore, a person skilled in the art can adopt embodiments in which these elements or all elements are replaced with equivalent elements, and these embodiments are also included in the scope of the invention.

### First Embodiment

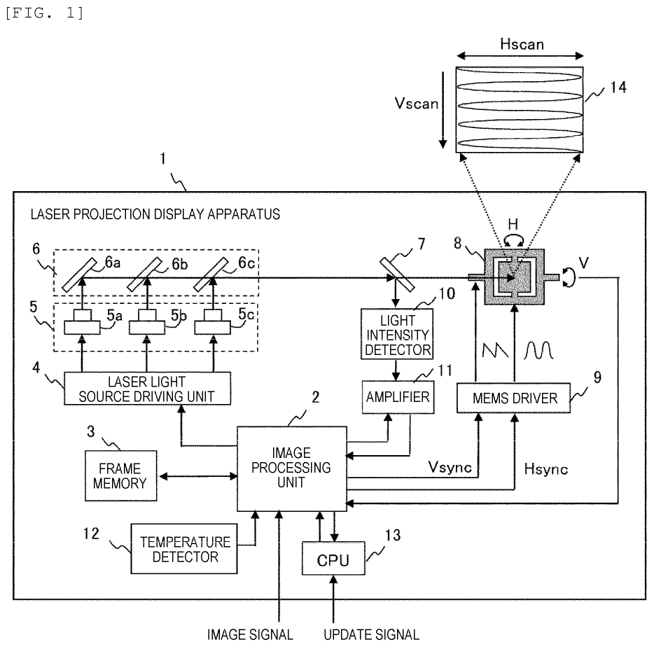

FIG. 1 is a block diagram showing an overall configuration of a laser projection display apparatus according to the first embodiment. A laser projection display apparatus 1 includes an image processing unit 2, a frame memory 3, a laser light source driving unit 4, a laser light source 5, a reflection mirror 6, a transmission mirror 7, a MEMS scanning mirror 8, a MEMS driver 9, a light intensity detector 10, an amplifier 11, a temperature detector 12, and a central processing unit (CPU) 13, and displays a display image 14 on a projection surface. The configuration and operation of each part will be explained.

The image processing unit 2 generates a horizontal synchronization signal (Hsync) and a vertical synchronization signal (Vsync) synchronized with an image signal input from the outside, and supplies the two signals to the MEMS driver 9. The horizontal synchronization signal and the vertical synchronization signal each include a display period for projecting an image and a blanking period for not projecting an image, which are called a horizontal display period and a horizontal blanking period, and a vertical display period and a vertical blanking period. The horizontal display period and the vertical display period are collectively referred to as a display period, and the horizontal period and the vertical blanking period are collectively referred to as the blanking period. A period corresponding to one image including the vertical display period and the vertical blanking period is called one frame.

The image processing unit 2 generates an image signal obtained by adding various corrections to an input image signal, and supplies the image signal to the laser light source driving unit 4. The various corrections performed by the image processing unit 2 include correction on an image distortion caused by scanning by the MEMS scanning mirror 8, a gradation adjustment according to the image signal level, and the like. Image distortion occurs due to different relative angles of the laser projection display apparatus 1 and a projection surface, optical axis deviation of the laser light source 5 and the MEMS scanning mirror 8, or the like.

The image processing unit 2 adjusts the intensity of the laser light by controlling the laser light source driving unit 4 based on intensity information of the laser light detected by the light intensity detector 10. The adjustment of the laser light includes determination of an overshoot current based on the update signal acquired from the CPU 13 or the temperature information detected by the temperature detector 12. The details of this overshoot current determination will be described later.

The laser light source driving unit 4 receives an image signal output from the image processing unit 2 and added with various corrections, and modulates the driving current of the laser light source 5 accordingly. The laser light source 5 has, for example, three semiconductor lasers 5a, 5b, and 5c for RGB, and emits RGB laser lights corresponding to the image signal for each one among RGB of the image signal.

The three laser lights of RGB are composited by the reflection mirror 6 having three mirrors 6a, 6b, and 6c and emitted to the transmission mirror 7. The reflection mirror 6 is made of a special optical element (dichroic mirror) that reflects light of a specific wavelength and transmits light of other wavelengths. Specifically, the reflection mirror 6 has a dichroic mirror 6a that reflects a laser light (for example, R light) emitted from the semiconductor laser 5a and transmits laser lights of other colors, a dichroic mirror 6b that reflects a laser light (for example, G light) emitted from the semiconductor laser 5b and transmits laser lights of other colors, and a dichroic mirror 6c that reflects a laser light (for example, B light) emitted from the semiconductor laser 5c and transmits other colors. As a result, the three laser lights of RGB are composited to one laser light to become projection light, and are emitted to the transmission mirror 7.

The transmission mirror 7 is a mirror that transmits a majority of the light and reflects a minority of the light. Therefore, a majority of the projection light which transmits through the transmission mirror 7 is incident on the MEMS scanning mirror 8. Meanwhile, a minority of the projection light which is reflected by the transmission mirror 7 proceeds to the light intensity detector 10.

The MEMS scanning mirror 8 is a scanning unit for an image, which has a two-axis rotation mechanism, and can vibrate a central mirror unit in two directions including the horizontal direction and the vertical direction. The vibration of the MEMS scanning mirror 8 is controlled by the MEMS driver 9. The MEMS driver 9 generates a sine wave signal synchronized with the horizontal synchronization signal from the image processing unit 2, and generates a sawtooth wave signal synchronized with the vertical synchronization signal to drive the MEMS scanning mirror 8.

The MEMS scanning mirror 8 receives a sine wave drive signal from the MEMS driver 9 and performs a sine wave resonance movement in the horizontal direction. At the same time, the MEMS scanning mirror 8 receives a sawtooth wave drive signal from the MEMS driver 9 and performs a unidirectional constant-speed movement in the vertical direction. Thereby, the projection light incident from the transmission mirror 7 is scanned on the projection surface with a trajectory (Hscan, Vscan) as shown in the display image 14. An input image is displayed on the projection surface by performing a laser light modulation operation by the laser light source driving unit 4 in synchronization with the scanning operation.

The light intensity detector 10 measures a light amount of the laser light directed toward the MEMS scanning mirror 8 by detecting the light reflected by the transmission mirror 7 among the projection light, and outputs the light amount of the laser light to the amplifier 11. The amplifier 11 amplifies an output of the light intensity detector 10 according to an amplification factor set by the image processing unit 2, and then outputs the amplified output to the image processing unit 2. The image processing unit 2 performs the overshoot current determination based on the output from the amplifier 11. This overshoot current determination is performed by appropriately adjusting the overshoot current during the vertical blanking period, which is a non-display period of the image, and detecting the respective laser light intensities of RGB at that time.

The temperature detector 12 measures an ambient temperature and outputs the same to the image processing unit 2. The image processing unit 2 performs the overshoot current determination when a certain amount of change occurs in the input temperature. This is because the light output characteristics of the semiconductor lasers 5a, 5b, and 5c with respect to the forward current have a temperature dependence. The temperature detector 12 is arranged in a housing of the laser projection display apparatus 1, for example, in the vicinity of the laser light source 5.

The CPU 13 controls the entire laser projection display apparatus 1 and receives a control signal from the outside. For example, when the CPU 13 receives an update signal for starting the overshoot current determination from the outside, the CPU 13 outputs the update signal to the image processing unit 2.

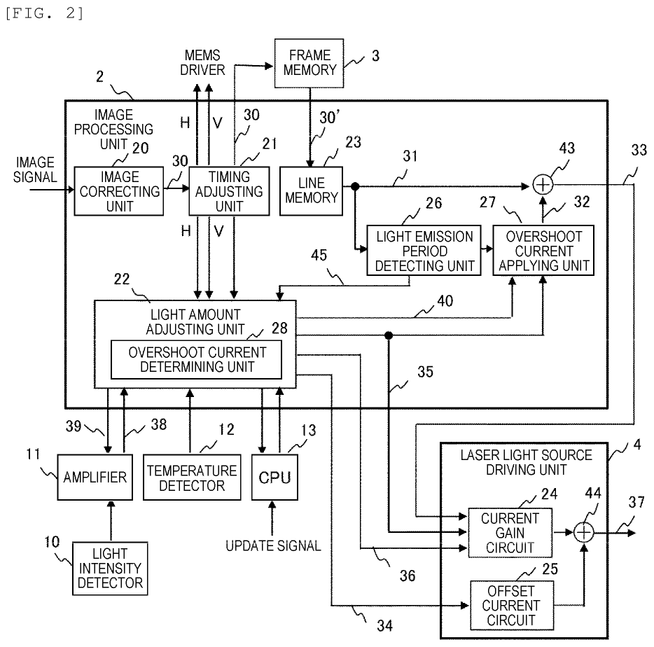

FIG. 2 is a diagram showing internal configurations of the image processing unit 2 and the laser light source driving unit 4 of FIG. 1. First, the configuration of the image processing unit 2 will be explained. The image signal input from the outside is input to an image correcting unit 20. The image correcting unit 20 performs the correction on image distortion caused by scanning by the MEMS scanning mirror 8, the gradation adjustment based on the image signal level on the input image, and the like. An image signal 30 after the correction is output to a timing adjusting unit 21.

The timing adjusting unit 21 generates a horizontal synchronization signal (H) and a vertical synchronization signal (V) and outputs the same to the MEMS driver 9 and alight amount adjusting unit 22. The image signal 30 after the correction, which is input from the image correcting unit 20, is temporarily stored in the frame memory 3. The image signal 30 written in the frame memory 3 is read out with a read signal synchronized with the horizontal synchronization signal and the vertical synchronization signal generated by the timing adjusting unit 21. As a result, an image signal 30′ read from the frame memory 3 is delayed by one frame with respect to the image signal 30 to be written.

The image signal 30′ read from the frame memory 3 is input to a line memory 23. The line memory 23 takes in image signals of one horizontal display period, reads the same out sequentially in the next horizontal display period, and then transmits an image signal 31 to a light emission period detecting unit 26 and an adder 43.

The light emission period detecting unit 26 analyses the image signal 31, detects a period during which the laser light source 5 emits light, that is, an elapsed time from the start of the light emission to the present for each pulse light emission, and outputs the period to an overshoot current applying unit 27.

The overshoot current applying unit 27 maintains overshoot current data 40 output from an overshoot current determining unit 28 in the light amount adjusting unit 22, and determines an overshoot current to be applied for each time based on the elapsed time from the start of the light emission output from the light emission period detecting unit 26. At that time, the overshoot current applying unit 27 outputs an overshoot application current 32 converted into an image signal to the adder 43 based on a gain setting signal 35 output from the light amount adjusting unit 22.

The adder 43 applies the overshoot application current 32 to the image signal 31 and supplies the same as a composite image signal 33 to the laser light source driving unit 4. Here, a clock frequency of transmitting the composite image signal 33 to the laser light source driving unit 4 may be different from a clock frequency of reading the image signal 30′ from the frame memory 3, but such difference can be adjusted by relaying the line memory 23 and using a frequency of writing to and reading from the line memory 23.

The light amount adjusting unit 22 inputs a signal (light intensity) 38 obtained by amplifying the output of the light intensity detector 10 by the amplifier 11, and controls the laser light source driving unit 4 such that an intensity of the projection light from the laser light source 5 becomes a target value. Specially, in the present embodiment, an overshoot current is applied to the image signal in order to improve the rising response of the laser light source 5. Therefore, the overshoot current determination is performed by the overshoot current determining unit 28. The details will be described later, but in the vertical blanking period that is the non-display period of the image, an overshoot current adjustment signal 36 of each color among RGB used for adjustment is supplied to the laser light source driving unit 4, and the intensity 38 of the projection light obtained at this time is measured. Then, the overshoot current adjustment signal 36 is adjusted such that the light intensity 38 to be measured becomes the target value. As a result, it is possible to cope with change in the rising response of the emission light intensity of each of the semiconductor lasers 5a, 5b, and 5c as the laser light amount fluctuates due to the ambient temperature change and the intensity of the laser light decreases due to deterioration with time.

The light amount adjusting unit 22 performs a laser light intensity adjustment separately from the overshoot current determination described above. The laser light intensity adjustment supplies a reference image signal (not shown) to the laser light source driving unit 4, and determines current setting signals such as an offset current setting signal 34 with respect to the laser light source driving unit 4 and a current gain setting signal 35 based on the intensity 38 of the obtained laser light. As a result, it is possible to maintain a projection image after a certain period of time (time required for the laser to sufficiently stand up) from the start of the light emission in a constant white balance.

Next, an operation of the laser light source driving unit 4 will be explained. The laser light source driving unit 4 is a current setting unit that converts the composite image signal 33 output by the adder 43 or the overshoot current adjustment signal 36 input from the overshoot current determining unit 28 to a current value supplied to the laser light source 5. The laser light source driving unit 4 has a current gain circuit 24 and an offset current circuit 25 for such current setting.

The current gain circuit 24 determines a signal current value (β×S) flowing through the laser light source 5 by multiplying an image signal value S of the composite image signal 33 or the overshoot current adjustment signal 36 by a current gain β. The current gain β at that time is given by a current gain setting signal 35 from the light amount adjusting unit 22. By increasing or decreasing the current gain β, a signal current value component proportional to the image composite image signal 33 or the overshoot current adjustment signal 36 is increased or decreased.

The offset current circuit 25 determines a lower limit value (offset component) of a current value flowing through the laser light source 5. An offset current value a at that time is given by the offset current setting signal 34 from the light amount adjusting unit 22. The offset current value a is a fixed value that does not depend on the composite image signal 33 or the overshoot current adjustment signal 36.

The adder 44 adds the offset current value a determined by the offset current circuit 25 to the signal current value (β×S) determined by the current gain circuit 24 and supplies a total current value 37 (=β×S+α) to the laser light source 5.

As described in the section of the problem to be solved, in the laser light source such as the semiconductor laser, there is a problem that the rising waveform of the emission light intensity becomes blunt. In the present embodiment, in order to solve this problem, the overshoot current is optimally applied to the image signal to drive the semiconductor laser. In order to cope with a change in the optical output characteristic (slope efficiency) of the semiconductor laser due to the ambient temperature change or a decrease in the intensity of the laser light due to deterioration with time, the overshoot current determination is performed. Hereafter, the overshoot current determination by the overshoot current determining unit 28 will be explained in detail below.

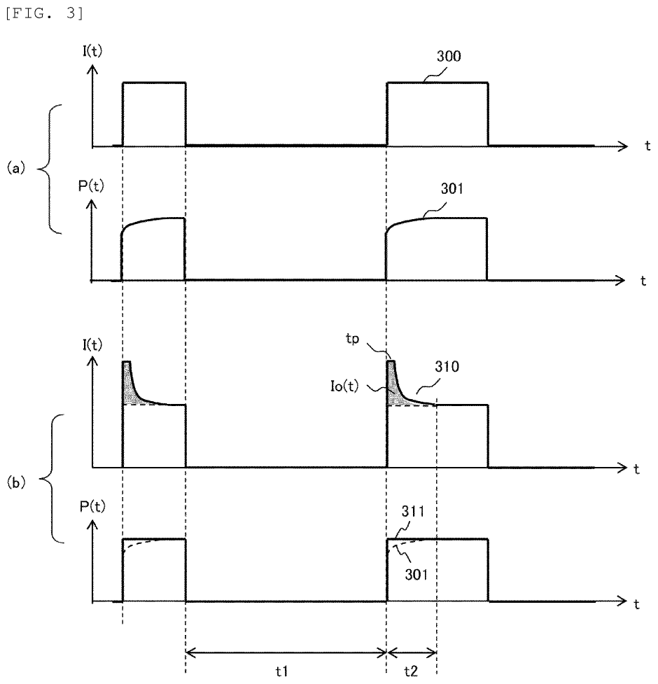

FIG. 3 is a diagram schematically explaining an effect of applying the overshoot current, and shows a relation between a driving current of the semiconductor laser and a light output waveform. FIG. 3(a) shows a time change of a driving current I(t) and a light output P(t) when only the image signal 31 is input to the laser light source driving unit 4. It is assumed that the image signal is a rectangular wave pulse 300 and is continuous with a sufficiently large non-light emission period t1. When the driving current I(t) has a rectangular wave shape, the light output P(t) becomes a waveform 301 having a blunt rising.

Meanwhile, FIG. 3(b) shows a case where an overshoot current Io(t) is applied to the driving current of FIG. 3(a) to obtain a waveform 310. The overshoot current Io(t) is applied so as to have a peak immediately after the start of the image signal (rising position of the rectangular wave pulse), and then the waveform is attenuated to zero during a duration period t2. As a result, the light output P(t) has an improved rising shape and approaches a rectangular wave 311.

The overshoot current to be applied in order to obtain a desired optical output waveform changes depending on the length of the preceding non-light emission period. This is because after the preceding light emission operation, a charge remains in a parasitic capacitance of a substrate on which the laser light source driving unit and the semiconductor laser are mounted, which affects the rising characteristic of the next light emission pulse. As an overshoot current serving as a reference (reference overshoot current), the overshoot current to be used when an immediately previous non-light emission period t1 is sufficiently large (a predetermined period t0 or more) is determined. The predetermined period t0 is a period until the charge is completely removed from the parasitic capacitance of the substrate on which the laser light source driving unit and the semiconductor laser are mounted, and is preferably 1 μs. Meanwhile, if the immediately previous non-light emission period t1 is small (smaller than the predetermined period t0), the reference overshoot current is used after being corrected by the overshoot current applying unit 27 as described below. In the following, unless otherwise specified, the overshoot current shall mean the reference overshoot current.

As shown in FIG. 3(b), the overshoot current Io(t) is attenuated to zero during the duration period t2, and a period tp is provided so that a leading peak value becomes constant. This is because by causing a peak current to flow for a certain period, the charge is quickly accumulated with respect to the parasitic capacitance, and as a result, the rising of the light output can be accelerated.

In order to determine an optimal overshoot current Io(t), the overshoot current determining unit 28 supplies the overshoot current adjustment signal 36 to the laser light source driving unit 4 to cause the laser light source 5 to emit light (monitor light emission), and detects (monitors) a light intensity at that time by the light intensity detector 10. Then, the detected light intensity is compared with the target light intensity, and feedback is performed in which the overshoot current is adjusted so that the target value can be obtained. As a result, the optimal overshoot current can be determined even if an ambient temperature change or deterioration with time is present.

Next, a timing at which the overshoot current determination is performed will be explained.

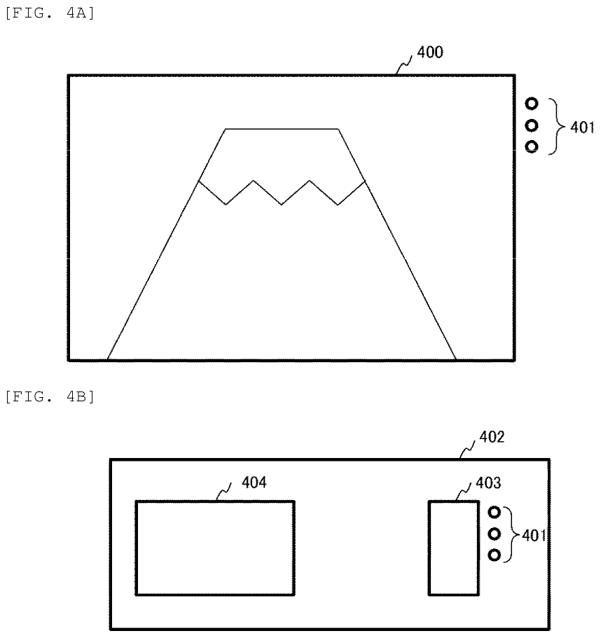

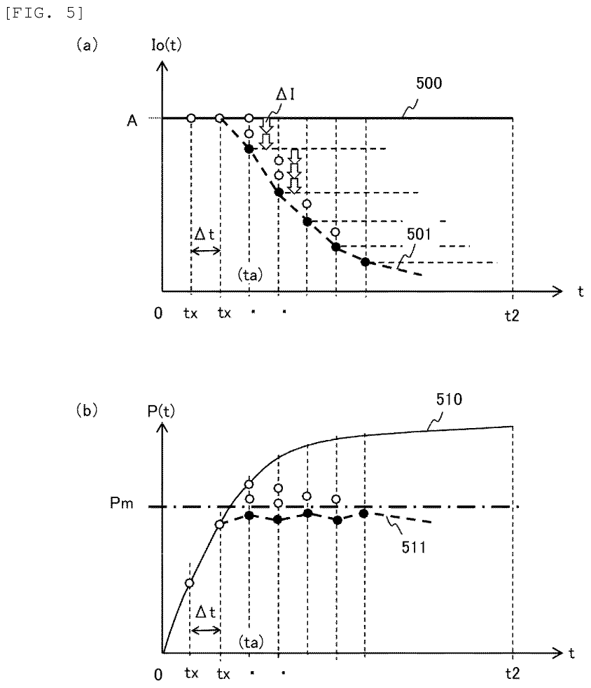

FIG. 4A is a diagram showing a case where the monitor light emission is performed during the vertical blanking period. A light emission position of a monitor light emission 401 by the overshoot current adjustment signal 36 is set outside an image area 400 during the vertical blanking period. Thereby, it is possible to monitor the light intensity without overlapping a projection image in the image area 400. The driving current used for the monitor light emission is not applied to the image signal, and thus the overshoot current determination can be executed at any position within the vertical blanking period.

FIG. 4B is a diagram showing an example of the monitor light emission in a light guide plate type display apparatus. A light guide plate type display apparatus 402 is a device in which an image input to an incident window 403 propagates in the light guide plate and displays an image on an emission window 404. As shown in FIG. 4B, by causing the monitor light emission 401 to emit light outside the incident window 403, the monitor light emitting 401 cannot be visually recognized from the emission window 404. A light intensity detector may be placed at a position to be hit by the monitor light emission 401 in the light guide plate type display apparatus 402. Thereby, not only the light intensity can be detected by the light intensity detector but also a scanning angle of the scanning mirror such as MEMS can be detected.

FIG. 5 is a diagram showing overshoot current determination by feedback. FIG. 5(a) shows a waveform of the overshoot current Io(t) applied in the monitor light emission, and FIG. 5(b) shows the time change P(t) of the light intensity of the laser light detected at that time. A time t is an elapsed time from the start of the light emission, and a duration time of light emission is t2. After the laser emission is started, the current value at each time position tx of the light emission period is adjusted to determine the waveform of the overshoot current such that the light intensity becomes the target value Pm.

First, as an initial value of the overshoot current Io(t), a rectangular wave 500 having an amplitude A is set to emit light, as shown in FIG. 5(a). The light intensity P(t) at that time becomes a waveform 510 rising in a curved shape as shown in FIG. 5(b) and exceeds the target value Pm along with the time t. Therefore, the overshoot current is decreased along with the time t so that the light intensity P is corrected so as to approach the target value Pm.

Specially, the time position tx of interest is increased by a unit time Δt at a time from the start of the light emission, and the light intensity P(tx) at that time position tx is compared with the target value Pm. The current from the time position tx immediately after the light intensity P exceeds the target value Pm to t2 is uniformly decreased by ΔI at a time, and the light intensity P at the time position tx of interest is adjusted to be lower than the target intensity Pm. When the light intensity P falls below the target intensity Pm, the current value at that time is determined as the current value at the time position tx. At the next time position tx, similarly, the current is decreased by ΔI and the light intensity P is adjusted to be lower than the target value Pm.

In this way, the current value at each time position tx is determined, and this process is repeated until the time position tx reaches t2, whereby a waveform 501 of the reference overshoot current Io(t) from t=0 to t2 is determined. The light intensity P(t) with respect to the reference overshoot current Io(t) is a waveform 511. The current is not adjusted and the amplitude A is maintained in a range of tx<ta, where ta is the time at which the light intensity P reaches the target intensity Pm. In the diagram, circle marks indicate determination points, and change amounts (Δt, ΔI) are displayed in an enlarged manner for the sake of explanation, but the change amounts are actually very small, and thus the light intensity P becomes a smooth waveform that coincides with the target value Pm.

Since one monitor light emission is performed for each determination, the light emission is performed for a large number of times. Therefore, if the processing is not completed during one vertical blanking period, the processing waits until the next vertical blanking period to continue the remaining processing.

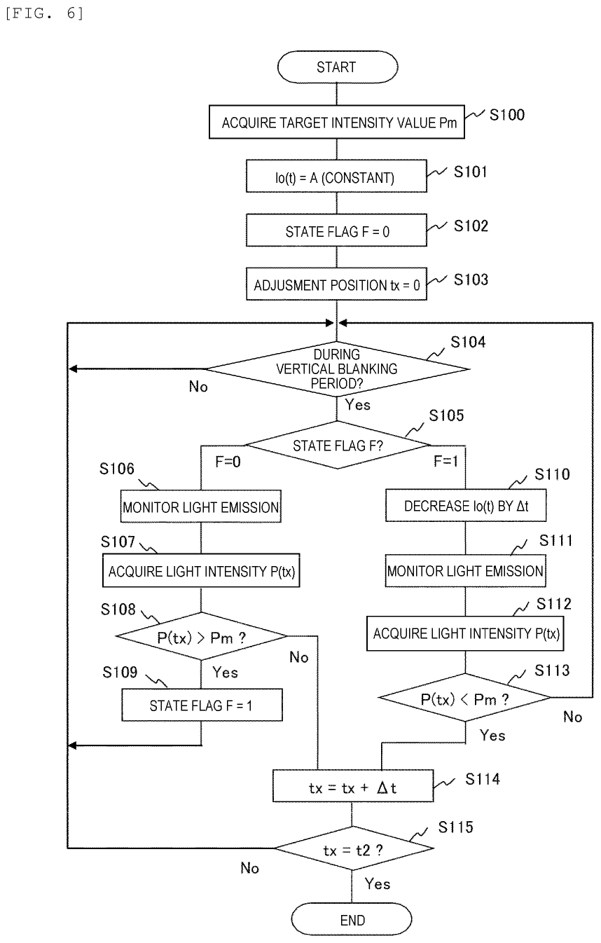

FIG. 6 is a flowchart of the overshoot current determination. The following processing is performed mainly by the overshoot current determining unit 28 in the image processing unit 2. The present flowchart starts based on an update signal acquired from the CPU 13 or temperature information (temperature change equal to or higher than a predetermined value) deleted by the temperature detector 12.

In S100, the monitor light emission 401 emits light and acquires a target intensity value Pm. The target intensity value Pm is a light intensity when the duration period t2 has elapsed from the laser light emission start. In S101, the overshoot current Io(t) is set to a constant A. In S102, a state flag F is reset (F=0). The meaning of the state flag F is that the state of having started the light emission and waiting until the light intensity reaches the target intensity value is F=0. On the other hand, a state where the overshoot current is adjusted after the light intensity reached the target intensity value so as to follow the target intensity value is F=1. In S103, as a time position at which the overshoot current Io(t) is adjusted, 0 is substituted into the variable tx indicating the elapsed time from the start of the light emission.

In S104, it is determined whether or not the current operation state is during the vertical blanking period. If the current operation state is not during the vertical blanking period, the processing waits until the current operation state enters the vertical blanking period. If the current operation state is during the vertical blanking period, the processing shifts to S105 to determine a value of the current state flag F. If the state flag F=0, the processing shifts to S106. If the state flag F=1, the processing shifts to S110. An initial determination is F=0, and thus the processing shifts to S106, and as the processing progresses, the state flag becomes F=1, so the processing proceeds to S110.

In S106, the monitor light emission 401 is performed with the overshoot current Io(t) of the currently set condition. In S107, the intensity P(tx) after the lapse of tx from the start of the light emission is acquired by the light intensity detector 10. In S108, it is determined whether or not the acquired light intensity P(tx) is larger than the target intensity value Pm. If the light intensity P(tx) is larger than the target value (S108, Yes), the processing shifts to S109, and the state flag becomes F=1. Then, the processing returns to S104. If the light intensity P(tx) is smaller than the target value (S108, No), the processing shifts to S114.

In S114, Δt is added to the variable tx. That is, the time position where the overshoot current Io(t) is adjusted is shifted by Δt. Here, Δt means a minimum resolution of the processing time and is desirably a unit time per light emission of the laser light source driving unit 4. Then, the processing shifts to S115 to determine whether or not the variable tx has reached the duration period t2 in which the overshoot current is applied. If the variable tx has not reached t2, the processing returns to S104. If the variable tx has reached t2, the present flowchart is ended and the overshoot current is determined.

If the state flag F=1 in the determination of S105, the processing of S110 and the subsequent steps are performed. In S110, the overshoot current Io(t) is adjusted and the current amount is uniformly decreased by ΔI in a section from t=tx to t2. For the section from t=0 to tx, previously set values are maintained. In S111, the monitor light emission 401 is performed by the overshoot current Io(t) after the adjustment, and in S112, the intensity P(tx) after the lapse of tx from the start of the light emission is acquired. In S113, it is determined whether or not the acquired light intensity P(tx) is smaller than the target intensity value Pm. If the light intensity P(tx) is smaller than the target value (S113, Yes), the processing shifts to S114, and Δt is added to the variable tx. If the light intensity P(tx) is larger than the target value (S1131, No), the processing shifts to S104.

As a result, when the state flag F=1, the current amount in the section from t=tx to t2 is decreased until the intensity P(tx) of the laser light at the time position of the variable tx falls below the target intensity value Pm. By repeating this step until the variable tx reaches t2, the shape of the optimal reference overshoot current Io(t) from t=0 to t2 can be determined.

In this way, it is possible to display a high-quality image that is unlikely to cause the user to visually recognize color unevenness by optimizing the applied waveform of the overshoot current with high accuracy by feedback during the vertical blanking period.

### Second Embodiment

In the second embodiment, the overshoot current determination processing is applied to the image signal on the screen instead of during the vertical blanking period. The configuration of the laser projection display apparatus 1 is similar to that of the first embodiment, but in FIG. 2, the overshoot current determining unit 28 receives elapsed time information 45 from the start of the light emission for each pulse light emission detected by the light emission period detecting unit 26, and applies the overshoot current in accordance with the timing of the start of the light emission. As a result, the monitor light emission 401 in the first embodiment is unnecessary, and it is not necessary to shade the monitor light emission. The current determination of the second embodiment is suitable when the initial value (previous determination value) of the overshoot current Io(t) is known in advance and is to be updated due to a temperature change or the like.

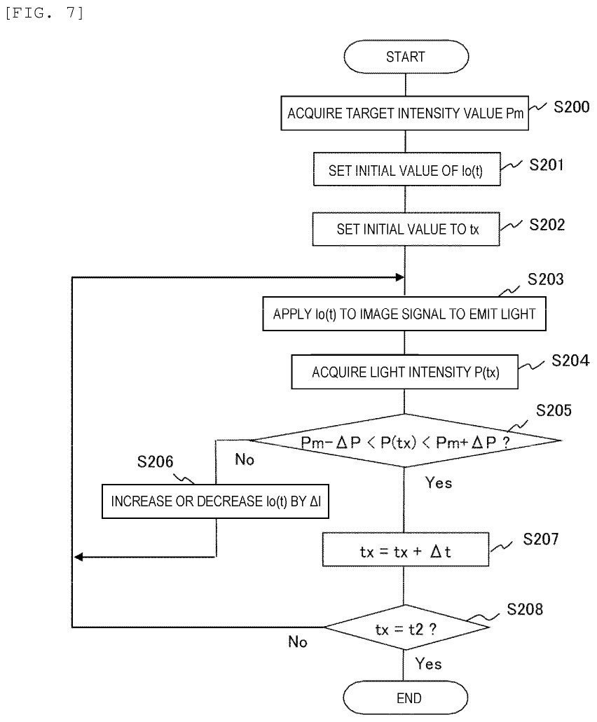

FIG. 7 is a flowchart of the overshoot current determination of the second embodiment. The overshoot current determination is performed mainly by the overshoot current determining unit 28 in the image processing unit 2.

In S200, the target intensity value Pm is acquired. The target intensity value Pm is a light intensity when the duration period t2 has elapsed from the laser light emission start. However, in the second embodiment, instead of acquiring the target intensity value during the vertical blanking period, based on the elapsed time information 45 received from the light emission period detecting unit 26, the target intensity value Pm is detected when the time t2 elapses from the start of the light emission of the image signal. In S201, the overshoot current Io(t) is set to a predetermined initial value. Alternatively, the overshoot current Io(t) is set to a previously determined overshoot current Io(t). The initial value set here is not the fixed value A (rectangular wave 500) as shown in FIG. 5(a), but the attenuation waveform as shown in Io(t) in FIG. 3(b). The reason is to prevent excessive light emission from occurring due to setting of the fixed value A, thereby preventing a user viewing the image from visually recognizing color unevenness.

In S202, the initial value is set to the variable tx which is the time position for adjusting the overshoot current. The variable tx is an elapsed time from the start of the light emission, and if the adjustment is started from a head position of the overshoot current, tx=0. It is desirable to set the time ta at which the light intensity P reaches the target intensity Pm as the initial value of the variable tx. As a result, the state flag in the first embodiment is set (F=1).

In S203, a currently set overshoot current Io (t) is applied to the image signal supplied to the laser light source driving unit 4 to cause the laser light source to emit light. A timing for application is determined based on the elapsed time information 45 from the light emission period detecting unit 26.

In S204, the intensity P(tx) after the lapse of tx from the start of the light emission is acquired by the light intensity detector 10. A timing for acquiring is determined based on the elapsed time information 45 from the light emission period detecting unit 26.

In S205, it is determined whether or not the intensity P(tx) of the acquired laser light falls within an allowable range (Pm±ΔP) of the target intensity value. If the intensity P(tx) of the acquired laser light falls within the allowable range (S205, Yes), the processing shifts to S207, and if the intensity P(tx) of the acquired laser light does not fall within the allowable range (S205, No), the processing shifts to S206.

In S206, the overshoot current Io(t) is adjusted (increased or decreased). That is, if the light intensity P(tx) is smaller than Pm−ΔP, the current amount in the period from t=tx to t2 is increased by ΔI, and if the light intensity P(tx) is larger than Pm+ΔP, the current amount of the period from t=tx to t2 is decreased by ΔI. Then, the processing returns to S203 and determines the overshoot current Io(t) after the adjustment.

In S207, Δt is added to the variable tx. Δt, as described in the first embodiment, shifts the time position at which the overshoot current Io(t) is adjusted. Then, the processing shifts to S208 and determine whether or not the variable tx has reached the duration period t2 in which the overshoot current is applied. If the variable tx has not reached t2, the processing returns to S203. If the variable tx has reached t2, the present flowchart is ended and the overshoot current is determined.

As a result, by operations of S203 to S206, the current amount in the section of t=tx to t2 is increased or decreased until the laser light intensity P(tx) at the position of the variable tx falls within the allowable range (±ΔP) of the target intensity value Pm. By repeating this step until the variable tx reaches t2, the shape of the optimal reference overshoot current Io(t) from t=0 to t2 can be determined.

As described above, in the second embodiment, the overshoot current is applied to the image signal in the screen to feedback the light intensity, and the waveform of the overshoot current applied to the target light intensity is optimized. In this way, without shading the monitor light emission or the like, it is possible to display a high-quality image that is unlikely to cause the user to visually recognize color unevenness.

### Third Embodiment

In the third embodiment, the overshoot current (reference overshoot current) determined in the first and second embodiments is corrected based on the image information in the screen, particularly lengths of preceding light emission period and non-light emission period. Therefore, a look-up table is prepared in which a correction amount is set with the lengths of the light emission period and the non-light emission period as parameters. As a result, even in a state where the interval between continuous light emission pulses is narrow and a charge at the time of a preceding pulse light emission remains, the optimal overshoot current (corrected overshoot current) can be applied.

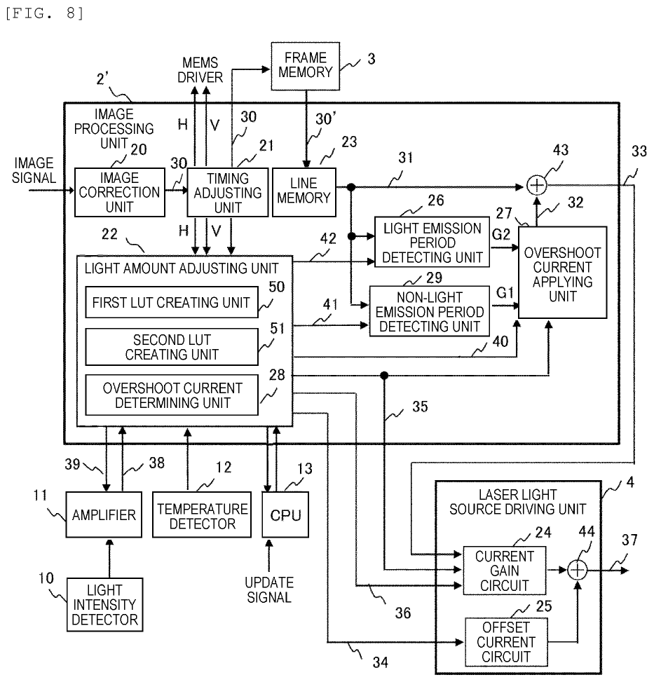

FIG. 8 is a diagram showing internal configurations of an image processing unit 2′ and the laser light source driving unit 4 of the third embodiment. The image processing unit 2 of the first embodiment is added with a non-light emission period detecting unit 29 that detects a non-light emission period of the image signal 31, a first lookup table (LUT) creating unit 50 that creates a first LUT with a preceding non-light emission period as a parameter, and a second LUT creating unit 51 that creates a second LUT with a preceding light emission period as a parameter.

The first LUT creating unit 50 of the light amount adjusting unit 22 performs first LUT creation described later, thereby creating a relation between the non-light emission period and a correction gain G1 (first LUT) and outputting first LUT data 41 to the non-light emission period detecting unit 29. The second LUT creating unit 51 performs second LUT creation described later, thereby creating a relation between a light emission period and a correction gain G2 (second LUT) and outputs second LUT data 42 to the light emission period detecting unit 26.

The light emission period detecting unit 29 detects a period during which the laser light source 5 is off, that is, an elapsed time (non-light emission period) from the end of light emission of a preceding pulse to the present. Subsequently, with reference to the first LUT data 41 acquired from the first LUT creating unit 50, the correction gain G1 corresponding to a detected non-light emission period is output to the overshoot current applying unit 27. The light emission period detecting unit 26 detects a light emission period of the preceding pulse. Subsequently, with reference to the second LUT data 42 acquired from the second LUT creating unit 51, the correction gain G2 corresponding to the detected non-light emission period is output to the overshoot current applying unit 27.

The overshoot current applying unit 27 uses the correction gain G1 acquired from the non-light emission period detecting unit 29 and the correction gain G2 acquired from the light emission period detecting unit 26 to calculate a correct coefficient K. Then, by multiplying the overshoot current data (reference overshoot current) 40 acquired from the overshoot current determining unit 28 by the correct coefficient K, the overshoot current is corrected and is output to the adder 43 as the overshoot application current 32.

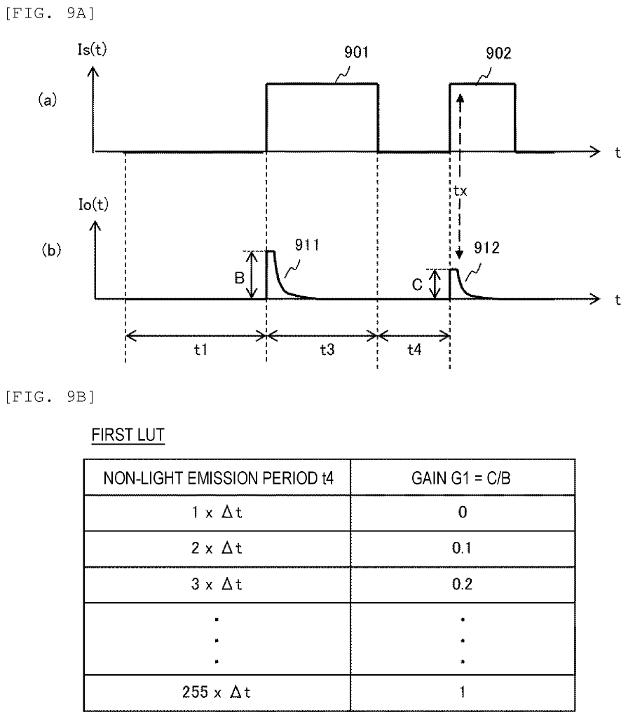

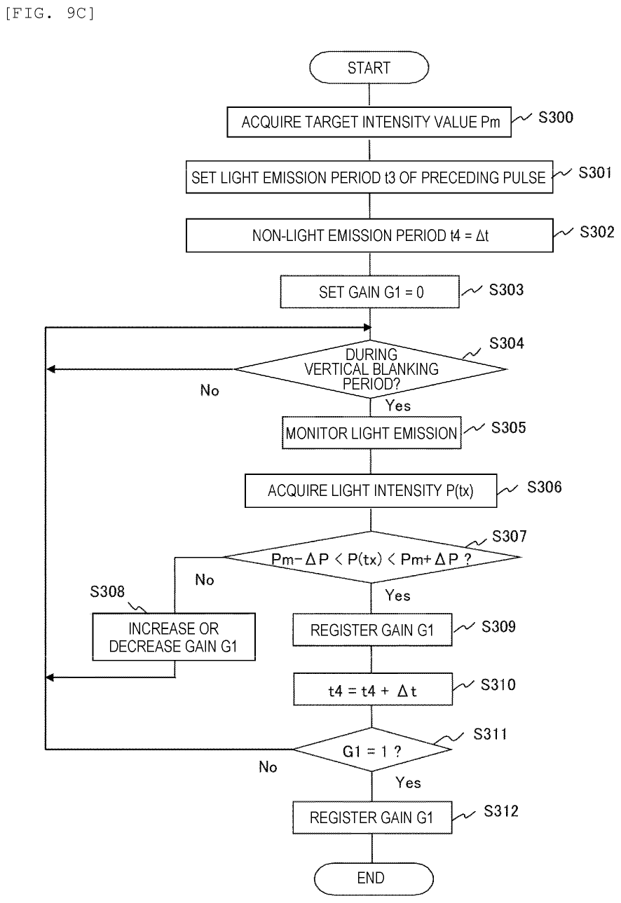

FIG. 9A to FIG. 9C are diagrams explaining the first LUT creation by the first LUT creating unit 50. In the first LUT creation, a length of the non-light emission period immediately before the light emission pulse is used as a parameter to determine the correction gain G1 of the overshoot current.

FIG. 9A is a diagram explaining correction of the overshoot current in accordance with the non-light emission period, where FIG. 9(a) is a time change Is(t) of the image signal 31, and FIG. 9(b) is a time change Io(t) of the overshoot current. Here, two continuous light emission pulses 901 and 902 as image signals and two overshoot currents 911 and 912 applied thereto are shown.

In the case of the light emission pulse 901 (light emission period t3), an immediately previous non-light emission period t1 is larger than a predetermined time t0 (time until the charge is completely removed). Therefore, the charge at the time of the previous light emission is completely removed, and thus a peak value B of the overshoot current 911 may remain a peak value (reference overshoot current) determined by the overshoot current determining unit 28.

Meanwhile, in the case of the light emission pulse 902, an immediately previous non-light emission period t4 is smaller than the predetermined time t0, and the charge of the light emission pulse 901 is not completely removed. Therefore, the overshoot current 912 to be applied is decreased to a peak value C, and the correction is made so that a desired light intensity waveform can be obtained.

An optimal peak value C changes depending on a length of the immediately previous non-light emission period t4. Therefore, the peak value C required for the light intensity to become a desired rectangular shape is obtained in advance by feedback, and the first LUT is created.

FIG. 9B is a diagram showing an example of the first LUT. In the first LUT, a peak value ratio (C/B) is represented by the gain G1 with the non-light emission period t4 as a parameter. When the non-light emission period t4 is large, a residual charge is small, and thus the gain G1 becomes larger. When the non-light emission period t4 is small, the residual charge is large, and thus the gain G1 becomes smaller.

FIG. 9C is a flowchart of the first LUT creation. The following processing is performed mainly by the first LUT creating unit 50 by performing the monitor light emission during the vertical blanking period. In the monitor light emission, in the two light emission pulses shown in FIG. 9A, the gain G1 of the overshoot current 912 applied to the subsequent pulse 902 is adjusted so that the light intensity during the rising period of the subsequent pulse 902 becomes the target value with the non-light emission period t4 as the parameter.

In S300, the monitor light emission is performed to acquire the target intensity value Pm. In S301, the light emission period t3 of the preceding pulse 901 is set to a predetermined time t30 or more. The predetermined time t30 is a time for accumulating a sufficient charge in the parasitic capacitance of the laser light source and is preferably 1 μs. In S302, Δt is set as the initial value in the immediately previous non-light emission period t4 as the parameter. In S303, the initial value of the gain G1 is set to 0.

In S304, it is determined whether or not the current operation state is during the vertical blanking period. If the current operation state is during the vertical blanking period, the processing shifts to S305, and if the current operation state is not during the vertical blanking period, the processing waits until the current operation state enters the vertical blanking period.

In S305, the overshoot current 912 is applied to the two light emission pulses 901 and 902 shown in FIG. 9A to perform the monitor light emission. The peak value C of the overshoot current 912 is set based on the gain G1 set currently. In S306, the laser light intensity P(tx) during the rising period (adjustment position tx) of the subsequent pulse 902 is acquired by the light intensity detector 10.

In S307, it is determined whether or not the intensity P(tx) of the acquired laser light falls within an allowable range (Pm±ΔP) of the target intensity value. If the laser light intensity P(tx) falls within the allowable range (S307, Yes), the processing shifts to S309, and if the laser light intensity P(tx) does not fall within the allowable range (S307, No), the processing shifts to S308.

In S308, the gain G1 is adjusted (increased or decreased). If the light intensity P(tx) is smaller than Pm−ΔP, the gain G1 is increased, and if the light intensity P(tx) is larger than Pm+ΔP, the gain G1 is decreased. Then, the processing returns to S304 and performs the monitor light emission based on the gain G1 after the adjustment.

In S309, the non-light emission period t4 set currently and the value of the gain G1 are registered in the first LUT. In S310, Δt is added to the non-light emission period t4. In step S311, it is determined whether or not the gain G1 has reached 1. If the gain G1 has not reached 1, the processing returns to S304, and the monitor light emission is performed based on a new non-light emission period t4. If the gain G1 has reached 1, the processing shifts to S312, and since the gain G1=1 after the current non-light emission period t4, the gain G1=1 is registered in the first LUT and the present flowchart is ended.

That is, by operations of S307 to S308, by repeating increasing or decreasing the gain G1 until the laser light intensity P(tx) falls within the allowable range (Pm±ΔP) of the target intensity value for each non-light emission period t4, the first LUT, which is the relation between the non-light emission period t4 and the gain G1, can be created.

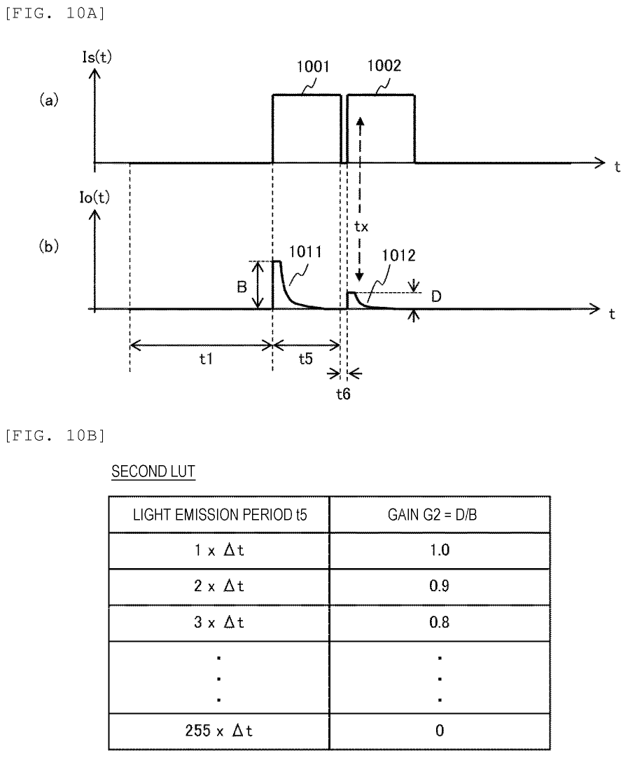

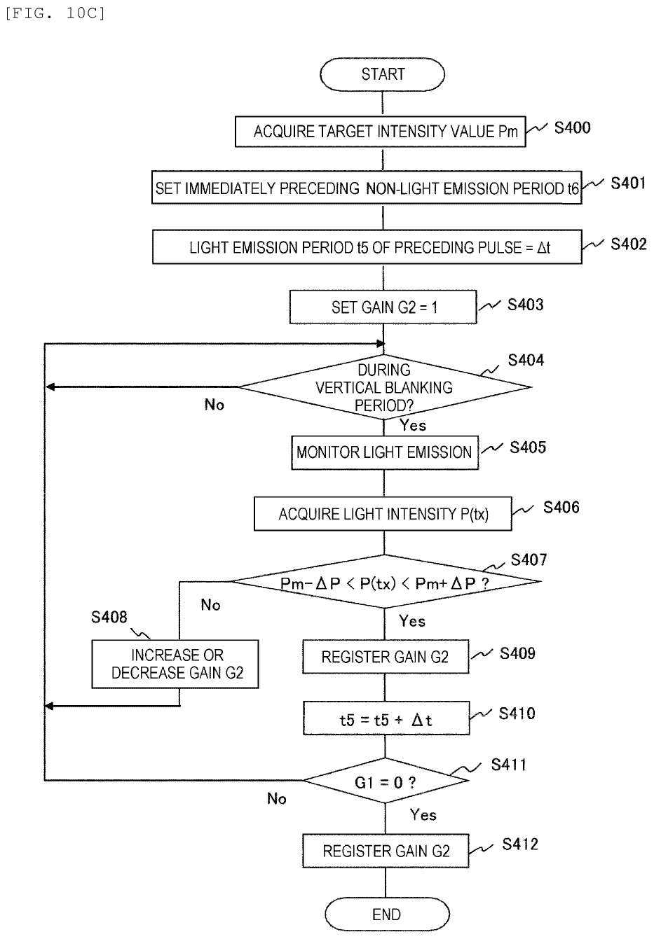

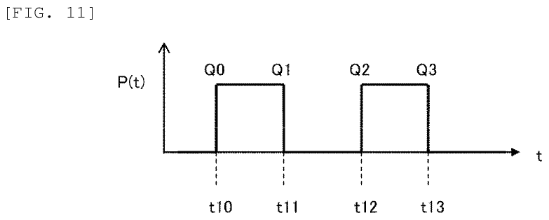

FIG. 10A to FIG. 10C are diagrams explaining the second LUT creation by the second LUT creating unit 51. In the second LUT creation, a length of the light emission period of a preceding light emission pulse is used as a parameter to determine the correction gain G2 of the overshoot current.

FIG. 10A is a diagram explaining correction of the overshoot current in accordance with the light emission period, FIG. 10(a) is the time change Is(t) of the image signal 31, and FIG. 10(b) is the time change Io(t) of the overshoot current. Here, two continuous light emission pulses 1001 and 1002 as image signals and two overshoot currents 1011 and 1012 applied thereto are shown. However, an interval (non-light emission period) t6 between the two light emission pulses 1001 and 1002 is significantly smaller than the predetermined time t0, so that the situation is easily affected by the preceding light emission pulse 1001.

In the case of the light emission pulse 1001 (light emission period t5), the immediately previous non-light emission period t1 is larger than the predetermined time t0 and the charge at the time of the previous light emission is completely removed, and thus a peak value B of the overshoot current 1011 may remain the peak value determined by the overshoot current determining unit 28.

Meanwhile, in the case of the light emission pulse 1002, an immediately previous non-light emission period t6 is significantly smaller than the predetermined time t0, and the charge of the preceding light emission pulse 1001 is completely removed. Therefore, the overshoot current 1012 to be applied is decreased to a peak value D, and the correction is made so that a desired light intensity waveform can be obtained.

An optimal peak value D depends on a length of the light emission period t5 of the preceding light emission pulse 1001. Therefore, the peak value D required for the light intensity to become a desired rectangular shape is obtained feedback while changing the light emission period t5, and the second LUT is created.

FIG. 10B is a diagram showing an example of the second LUT. In the second LUT, a peak value ratio (C/D) is represented by the gain G2 with the light emission period t5 as a parameter. When the light emission period t5 is small, the residual charge is small, and thus the gain G2 becomes larger. When the light emission period t5 is large, the residual charge is large, and thus the gain G2 becomes smaller.

FIG. 10C is a flowchart of the second LUT creation. The following processing is performed mainly by the second LUT creating unit 51 by performing the monitor light emission during the vertical blanking period. In the monitor light emission, in the two light emission pulses shown in FIG. 10A, the gain G1 of the overshoot current 1012 applied to the subsequent pulse 1002 is adjusted so that the light intensity during the rising period of the subsequent pulse 1002 becomes the target value with the light emission period t5 of the preceding pulse 1001 as the parameter.

In S400, the monitor light emission is performed to acquire the target intensity value Pm. In S401, the immediately previous non-light emission period t6 is set to a predetermined time t60 or less. The predetermined time t60 is preferably set to 50 ns in order to minimize the change in the parasitic capacitance of the laser light source. In S402, Δt is set as the initial value in the light emission period t5 of the preceding pulse as the parameter. In S403, the initial value of the gain G2 is set to 1.

In S404, it is determined whether or not the current operation state is during the vertical blanking period. If the current operation state is during the vertical blanking period, the processing shifts to S405, and if the current operation state is not during the vertical blanking period, the processing waits until the current operation state enters the vertical blanking period.

In S405, the overshoot current 1012 is applied to the two light emission pulses 1001 and 1002 shown in FIG. 10A to perform the monitor light emission. The peak value D of the overshoot current 1012 is set based on the gain G2 set currently. In S406, the laser light intensity P(tx) during the rising period (adjustment position tx) of the subsequent pulse 1002 is acquired by the light intensity detector 10.

In S407, it is determined whether or not the intensity P(tx) of the acquired laser light falls within the allowable range (Pm±ΔP) of the target intensity value. If the laser light intensity P(tx) falls within the allowable range (S407, Yes), the processing shifts to S409, and if the laser light intensity P(tx) does not fall within the allowable range (S407, No), the processing shifts to S408.

In S408, the gain G2 is adjusted (increased or decreased). If the light intensity P(tx) is smaller than Pm−ΔP, the gain G2 is increased, and if the light intensity P(tx) is larger than Pm+ΔP, the gain G2 is decreased. Then, the processing returns to S404 and performs the monitor light emission based on the gain G2 after the adjustment.

In S409, the light emission period t5 set currently and the value of the gain G1 are registered in the second LUT. In S410, Δt is added to the light emission period t5. In S411, it is determined whether or not the gain G2 has reached 0. If the gain G1 has not reached 0, the processing returns to S404, and the monitor light emission is performed based on anew light emission period t5. If the gain G2 has reached 0, the processing shifts to S412, and since the gain G1=0 after the current light emission period t5, the gain G1=1 is registered in the second LUT and the present flowchart is ended. Instead of the determination in S411, the present flowchart may be ended when the light emission period t5 reaches a predetermined sufficiently long time.

That is, by operations of S407 to S408, by repeating increasing or decreasing the gain G2 until the laser light intensity P(tx) falls within the allowable range (Pm±ΔP) of the target intensity value for each light emission period t5, the second LUT, which is the relation between the light emission period t5 and the gain G2, can be created.

Next, a method for calculating the correct coefficient Kin the overshoot current applying unit 27 will be explained. FIG. 11 shows a schematic diagram when the light emission period and the non-light emission period are repeated in order to explain the method for calculating the correction coefficient K. Virtual charge amounts of times t10 and t12 at which transition from the non-light emitting period to the light emitting period occurs are represented by Q₀ and Q₂ (Q₂ₙ), and virtual charge amounts of times t11 and t13 at which transition from the light emission period to the non-light emission period occurs are represented by Q₁ and Q₃ (Q₂ₙ₊₁). At this time, the following equation is established from the relation of charging and discharging of the charge.

Q₂ₙ=Q₂ₙ₋₁×(1−G1)

Q₂ₙ₊₁=(1−G2)+G2×Q₂ₙ

K=(1−Q₂ₙ)

G1 and G2 are gains explained in FIG. 9 to FIG. 10.

In this way, the gain G1 obtained from the non-light emission period detecting unit 29 via the first LUT and the gain G2 obtained from the light emission period 26 via the second LUT are substituted into the equation to calculate the correct coefficient K of light emission starting points t10 and t12. Then, by multiplying the overshoot current data by the correct coefficient K, the overshoot current to be actually applied is determined.

In this way, in the third embodiment, the overshoot current is corrected based on the image information in the screen, in particular, the lengths of the light emission period and the non-light emission period. Therefore, even in the case of an image signal in which the interval between emission pulses is narrow, it is possible to display a high-quality image that is unlikely to cause a user to visually recognize color unevenness.

A laser projection display apparatus using a MEMS scanning mirror has been explained in each of the embodiments, but the invention is not limited to this and can be applied to any display apparatus using a laser light source such as a head-mounted display or a laser headlight.

### REFERENCE SIGN LIST

1 laser projection display apparatus
2 image processing unit
3 frame memory
4 laser light source driving unit
5 laser light source
6 reflection mirror
7 transmission mirror
8 MEMS scanning mirror
9 MEMS driver
10 light intensity detector
11 amplifier
12 temperature detector
13 CPU
14 display image
20 image correcting unit
21 timing adjusting unit
22 light amount adjusting unit
23 line memory
24 current gain circuit
25 offset current circuit
26 light emission period detecting unit
27 overshoot current applying unit
28 overshoot current determining unit
29 non-light emission period detecting unit
30, 31 image signal
32 overshoot application current
33 composite image signal
34 offset current setting signal
35 gain setting signal
36 overshoot current adjustment signal
37 output current
38 laser light intensity (P)
39 amplification factor
40 overshoot current data
41 first LUT data
42 second LUT data
43, 44 adder
45 elapsed time information
50 first LUT creating unit
51 second LUT creating unit
Io(t) overshoot current

1. A laser projection display apparatus configured to display an image by projecting laser lights of a plurality of colors in accordance with an image signal, the laser projection display apparatus comprising:
a laser light source configured to generate the laser lights of a plurality of colors;
a laser light source driving unit configured to drive the laser light source in accordance with the image signal;
a light intensity detector configured to detect an intensity of the laser lights emitted from the laser light source;
an overshoot current determining unit configured to determine a reference overshoot current for improving a rising response of the laser light source; and
an overshoot current applying unit configured to apply an overshoot current to the image signal based on the reference overshoot current determined by the overshoot current determining unit, wherein
the overshoot current determining unit supplies the overshoot current to the laser light source driving unit while changing the overshoot current, so as to cause the laser light source to emit light, and determines the reference overshoot current such that the light intensity detected by the light intensity detector when the laser light source emits light becomes a target value.

2. The laser projection display apparatus according to claim 1, further comprising:
a light emission period detecting unit configured to detect a light emission period during which the laser light source emits light; and
a non-light emission period detecting unit configured to detect a non-light emission period during which the laser light source is off, wherein
the overshoot current applying unit corrects the reference overshoot current determined by the overshoot current determining unit in accordance with a length of a light emission period of a preceding image signal detected by the light emission period detecting unit and a length of an immediately previous non-light emission period detected by the non-light emission period detecting unit, and then applies the corrected reference overshoot current to the image signal.

3. The laser projection display apparatus according to claim 2, wherein
when a length of an immediately previous non-light emission period t1 detected by the non-light emission period detecting unit is 1 μs or more, the overshoot current applying unit applies the reference overshoot current determined by the overshoot current determining unit to the image signal as it is.

4. The laser projection display apparatus according to claim 2, further comprising:
a first lookup table (first LUT) creating unit configured to create a first LUT showing a relation with a correction gain G1 with respect to the reference overshoot current using an immediately previous non-light emission period t4 detected by the non-light emission period detecting unit as a parameter, when a preceding light emission period t3 detected by the light emission period detecting unit is a predetermined value t30 or more; and
a second lookup table (second LUT) creating unit configured to create a second LUT showing a relation with a correction gain G2 with respect to the reference overshoot current using a light emission period t5 of the preceding image signal detected by the light emission period detecting unit as a parameter, when an immediately previous non-light emission period t6 detected by the non-light emission period detecting unit is a predetermined value t60 or less, wherein
the overshoot current applying unit calculates a correct coefficient K to be applied to the reference overshoot current based on the correction gain G1 obtained from the non-light emission period t4 detected by the non-light emission period detecting unit and the first LUT, and the correction gain G2 obtained from the light emission period t5 detected by the light emission period detecting unit and the second LUT.

5. The laser projection display apparatus according to claim 4, wherein
the predetermined value t30 is 1 μs and the predetermined value t60 is 50 ns.

6. The laser projection display apparatus according to claim 1, further comprising:
a temperature detector configured to detect an ambient temperature, wherein
the overshoot current determining unit updates the reference overshoot current when a detection value of the temperature detector changes or when an update signal is received from the outside.

7. The laser projection display apparatus according to claim 6, wherein
the overshoot current determining unit supplies the overshoot current to the laser light source driving unit while changing the overshoot current in a state where the overshoot current is applied to the image signal, so as to cause the laser light source to emit light, and updates the reference overshoot current such that the light intensity detected by the light intensity detector when the laser light source emits light becomes the target value.

8. The laser projection display apparatus according to claim 4, further comprising:
a temperature detector configured to detect an ambient temperature, wherein
the first LUT creating unit and the second LUT creating unit update the first LUT and the second LUT when a detection value of the temperature detector changes or when an update signal is received from the outside.

9. A method for driving a laser light source when displaying an image by projecting laser lights of a plurality of colors in accordance with an image signal, the method for driving a laser light source comprising:
determining a reference overshoot current for improving a rising response of the laser light source in advance; and
driving the laser light source by applying an overshoot current on the image signal based on the determined reference overshoot current, wherein
determining the reference overshoot current includes: supplying the overshoot current while changing the overshoot current, so as to cause the laser light source to emit light; and determining the reference overshoot current such that the light intensity detected when the laser light source emits light becomes a target value.

10. The method for driving the laser light source according to claim 9, further comprising:
detecting a period during which the laser light source emits light; and
detecting a period during which the laser light source is off, wherein
driving the laser light source includes:
correcting the reference overshoot current in accordance with a length of a light emission period of a preceding image signal and a length of an immediately before the non-light emission period, and then applying the corrected reference overshoot current to the image signal.
